(19) United States
(12) Patent Application Publication
(10) Pub. No.: US 2016/0126401 A1
(43) Pub. Date: May 5, 2016

(54) TANDEM PHOTOVOLTAIC DEVICE

(71) Applicant: SRU CORPORATION, Pasadena, CA (US)

(72) Inventors: John Iannelli, San Marino, CA (US); Brian D. Hunt, La Crescenta, CA (US)

(21) Appl. No.: 14/925,601

(22) Filed: Oct. 28, 2015

Related U.S. Application Data
(60) Provisional application No. 62/069,938, filed on Oct. 29, 2014.

(51) Int. Cl. H01L 31/0725; H01L 31/18; H01L 31/032; H01L 31/028; H01L 31/0224; H01L 31/0236

(52) U.S. Cl. CPC H01L 31/0725; H01L 31/022466; H01L 31/02366; H01L 31/0322; H01L 31/028; H01L 31/1804; H01L 31/1884

(57) ABSTRACT

A tandem solar cell. The tandem solar cell includes a bottom cell, a joining layer directly on the bottom cell, and a top cell directly on the joining layer. The bottom cell is a silicon solar cell and the joining layer includes a transparent conductive oxide layer. The transparent conductive layer facilitates the flow of current through the device, and passivates the silicon bottom cell.

### CROSS-REFERENCE TO RELATED APPLICATION(S)

The present application claims priority to and the benefit of U.S. Provisional Application No. 62/069,938, filed Oct. 29, 2014, entitled “Chalcopyrite on Silicon Tandem Solar Cells”, the entire content of which is incorporated herein by reference.

### FIELD

One or more aspects of embodiments according to the present invention relate to solar cells, and more particularly to a tandem photovoltaic device.

### BACKGROUND

Silicon solar cells may be capable of converting light with a wavelength greater than approximately 400 nm and less than approximately 1100 nm to electrical power. The conversion efficiency of a silicon solar cell for wavelengths significantly shorter than 1100 nm is increasingly poor with decreasing wavelength, because a corresponding increasing portion of the energy of each photon is dissipated as heat.

A tandem solar cell may include a top cell having a higher band gap than silicon, and, accordingly capable of more efficiently converting short-wavelength light to electrical power. If the top cell is transparent to longer wavelengths, then it may be assembled with a bottom cell, which may be a silicon solar cell, so that the bottom cell may convert the light transmitted through the top cell to electrical power.

In a tandem solar cell, optical loss at the interface between the top cell and the bottom cell, as well as recombination loss at any of the surfaces of the top and bottom cell, may result in a loss of overall efficiency. A further consideration may be manufacturability, i.e., whether a given tandem solar cell structure may be readily fabricated.

Thus, there is a need for a tandem photovoltaic device with high efficiency that may be readily fabricated.

### SUMMARY

According to an embodiment of the present invention there is provided a tandem solar cell, including: a first cell configured to generate a photoelectric current when illuminated with light; a joining layer directly on the first cell; and a second cell configured to generate a photoelectric current when illuminated with light, the second cell being directly on the joining layer, wherein the first cell is a silicon solar cell and the joining layer includes a first transparent conductive oxide layer.

In one embodiment, the joining layer is a simple layer of a transparent conductive oxide.

In one embodiment, the joining layer is less than 1 micron thick.

In one embodiment, the joining layer further includes a layer of silicon dioxide, the layer of silicon dioxide being directly on the first cell.

In one embodiment, the layer of silicon dioxide has a plurality of holes.

In one embodiment, the first transparent conductive oxide layer is directly on the layer of silicon dioxide; and one of the plurality of holes is a through hole extending from a first surface of the layer of silicon dioxide to a second surface of the layer of silicon dioxide, the first surface of the layer of silicon dioxide being directly on the first cell, and the first transparent conductive oxide layer being directly on the second surface of the layer of silicon dioxide.

In one embodiment, one of the plurality of holes contains a metal contact forming a conductive path between the first transparent conductive oxide layer and the first cell.

In one embodiment, the layer of silicon dioxide is less than 5 nm thick.

In one embodiment, the transparent conductive oxide is aluminum-doped zinc oxide.

In one embodiment, the transparent conductive oxide is indium-doped tin oxide.

In one embodiment, the transparent conductive oxide is a material selected from the group consisting of titanium-doped indium oxide, zinc oxide, boron-doped zinc oxide, gallium-doped zinc oxide, vanadium oxide, molybdenum oxide, indium-doped molybdenum oxide, titanium dioxide, fluorine-doped tin oxide, and combinations thereof.

In one embodiment, the second cell includes a layer of copper indium gallium sulfide.

In one embodiment, the copper indium gallium sulfide has a bandgap of about 1.7 eV.

In one embodiment, the second cell further includes a layer of cadmium sulfide directly on the layer of copper indium gallium sulfide.

In one embodiment, the second cell further includes a second transparent conductive oxide layer directly on the layer of cadmium sulfide.

In one embodiment, the second cell includes a layer of copper gallium diselenide.

In one embodiment, the second cell includes a material selected from the group consisting of perovskites, amorphous silicon, cadmium telluride, cadmium zinc telluride, cadmium magnesium telluride, and combinations thereof.

In one embodiment, the first cell has a textured top surface.

According to an embodiment of the present invention there is provided a method of fabricating a tandem solar cell, the method including: forming a joining layer directly on a silicon solar cell configured to generate a photoelectric current when illuminated with light, the joining layer including a transparent conductive oxide layer; and forming a second solar cell directly on the joining layer, the second solar cell being configured to generate a photoelectric current when illuminated with light.

In one embodiment, the forming of the joining layer consists of forming the transparent conductive oxide layer directly on the silicon solar cell.

In one embodiment, the forming of the joining layer includes: forming a layer of silicon dioxide directly on the silicon solar cell; and forming the transparent conductive oxide layer directly on the layer of silicon dioxide.

In one embodiment, the layer of silicon dioxide is less than 5 nm thick.

In one embodiment, the forming of the joining layer further includes: forming a plurality of through holes in the layer of silicon dioxide; and forming a metal contact in each of the plurality of through holes.

### BRIEF DESCRIPTION OF THE DRAWINGS

These and other features and advantages of the present invention will be appreciated and understood with reference to the specification, claims, and appended drawings wherein:

FIG. 1 is a schematic side view of a tandem solar cell, according to an embodiment of the present invention;

FIG. 2 is a detailed schematic side view of a tandem solar cell, according to an embodiment of the present invention;

FIG. 3 is a band diagram of a tandem solar cell, according to an embodiment of the present invention;

FIG. 4 is a band diagram of a tandem solar cell, according to another embodiment of the present invention;

FIG. 5 is a schematic side view of a tandem solar cell, according to an embodiment of the present invention; and

FIG. 6 is a schematic side view of a tandem solar cell, according to an embodiment of the present invention.

### DETAILED DESCRIPTION

The detailed description set forth below in connection with the appended drawings is intended as a description of exemplary embodiments of a tandem photovoltaic device provided in accordance with the present invention and is not intended to represent the only forms in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

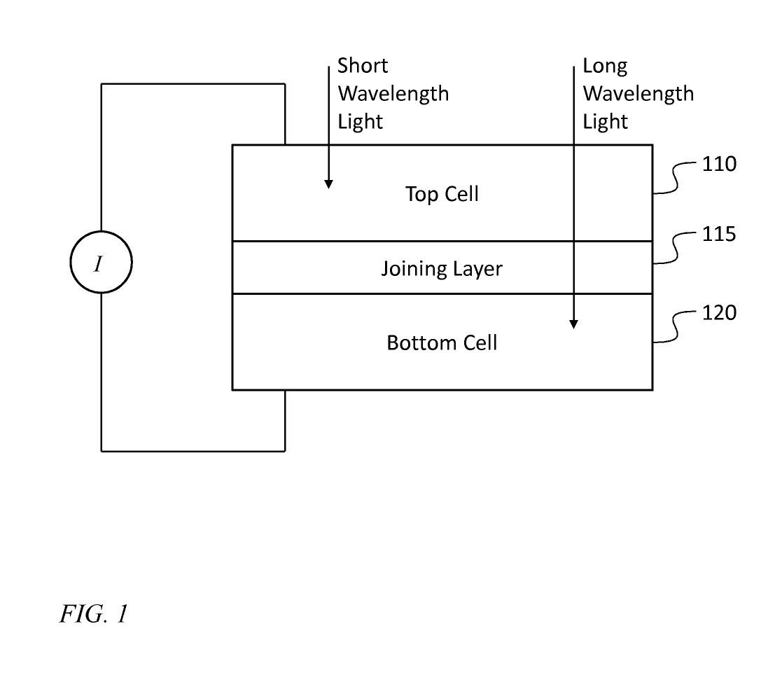

Referring to FIG. 1, in one embodiment a tandem solar cell includes a top cell 110, a joining layer 115, and a bottom cell 120, forming a structure referred to herein as a “monolithic tandem cell”. The term “monolithic” distinguishes the structure of FIG. 1, in which current flows in series through the top cell 110 and the bottom cell 120, from related art structures that may be referred to as “mechanically stacked tandem cells”, in which additional external connections are made to respective electrodes on the bottom surface of the top cell 110 and on the top surface of the bottom cell 120.

In the monolithic tandem cell of FIG. 1, the top cell 110 may absorb, and convert to electrical power, short wavelength light, e.g., light with a wavelength of less than approximately 700 nm. Long wavelength light, e.g., light with a wavelength greater than approximately 700 nm, may be transmitted through the top cell 110, and absorbed and converted to electrical power in the bottom cell 120. The top cell 110 and the bottom cell 120 are connected in series, so that the current I flowing through the top cell 110 is equal to the current flowing through the joining layer 115 and through the bottom cell 120, and the voltage across the output terminals of the monolithic tandem cell is the sum of the voltage across the top cell 110, the voltage across the joining layer 115, and the voltage across the bottom cell 120. The efficiency of the monolithic tandem solar cell may generally be higher if the photocurrents generated by the top cell 110 and the bottom cell 120 are approximately equal, than if they differ significantly. In one embodiment the joining layer 115 is directly on the bottom cell 120, and the top cell 110 is directly on the joining layer 115.

As used herein, a solar cell is a photovoltaic device that when provided with a front (top) metal electrode (e.g., an array of metal grid lines) and a back (bottom) metal electrode and illuminated with visible light will generate a potential difference across the electrodes. A solar cell may include one or two electrodes or, in some embodiments, no electrodes; for example, the top cell 110 and the bottom cell 120 of FIG. 1 include one electrode each.

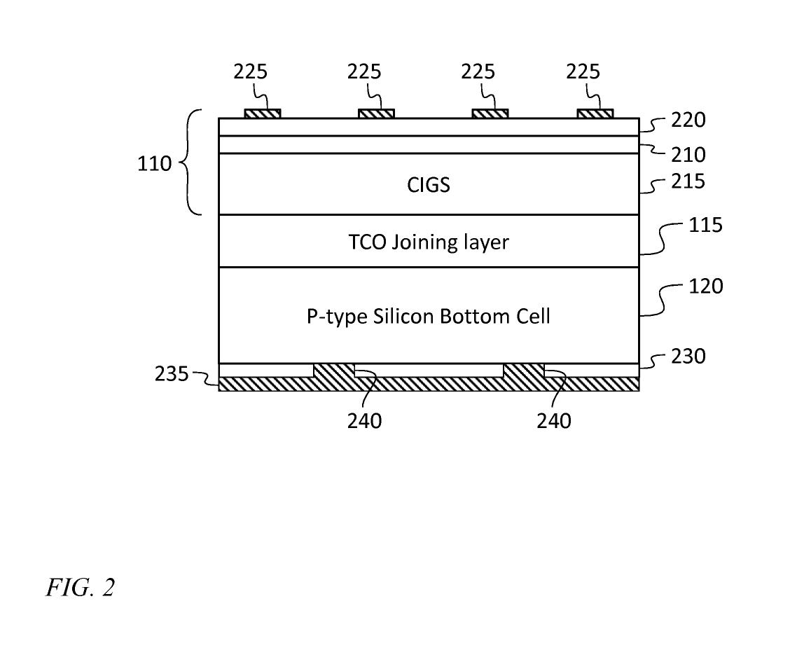

The top cell 110 may be any solar cell that converts a portion of the solar spectrum to electrical power, and transmits (i.e., is at least partially transparent to) another portion of the solar spectrum. The bottom cell 120 may be any solar cell that converts to electrical power at least a portion of the solar spectrum transmitted by the top cell 110. The joining layer may be any layer that allows current to flow from the top cell 110 to the bottom cell 120, and that is at least partially transparent. The joining layer 115 may have other properties, e.g., it may passivate the top surface of the bottom cell 120 and possibly the bottom surface of the top cell 110. Referring to FIG. 2, in one embodiment the top cell 110 is a CIGS solar cell, the joining layer 115 is a transparent conducting oxide (TCO) and the bottom cell 120 is a silicon solar cell. The top cell 110 may include a layer of cadmium sulfide (CdS) 210 on a layer of CIGS 215. As will be understood by those of skill in the art, CIGS is a family of materials including copper indium gallium sulfide and copper gallium diselenide (which may also be referred to as copper gallium selenide (CGS)). The bandgap of the CIGS may be controlled by appropriate selection of the proportions of indium and gallium in the CIGS, with the bandgap increasing as the proportion of gallium is increased. In this manner the cutoff wavelength of the CIGS (i.e., the wavelength of light corresponding to the bandgap) may be adjusted, adjusting the fraction of light that it transmitted through the top cell 110 and the potential current generation in the top cell 110. In one embodiment the composition of the CIGS is selected so that the bandgap is 1.7 eV. The CIGS layer may be inherently p-type as a result of copper vacancies. The top cell 110 may include a top TCO layer 220 and a set of metal gridlines 225 that together may provide a current path to the top surface of the layer of cadmium sulfide 210. The TCO layer that forms, or that forms part of, the joining layer 115 may be referred to as the bottom TCO layer.

The silicon solar cell may be a monocrystalline, or “crystalline” silicon solar cell, or it may be a polycrystalline silicon solar cell. The silicon solar cell may include a bottom passivation layer 230. The bottom passivation layer may be composed of any material suitable for passivating the bottom surface of the silicon solar cell, such as silicon dioxide (SiO₂) or aluminum oxide (Al₂O₃). The silicon solar cell may further include a bottom electrode including a back contact metal layer 235 covering the bottom surface of the bottom cell 120 and contacting silicon through a number of holes 240. The holes 240 may be formed in the bottom passivation layer 230 before the back contact metal layer 235 is deposited.

The bottom TCO layer may be a layer of aluminum-doped zinc oxide (AZO). The doping (with aluminum) of this TCO may result in this material being heavily n-doped. The bottom cell 120 may be a p-type silicon solar cell, consisting of a p-type substrate (which may be referred to as the base) covered by a thin n⁻-doped layer (which may be referred to as the emitter).

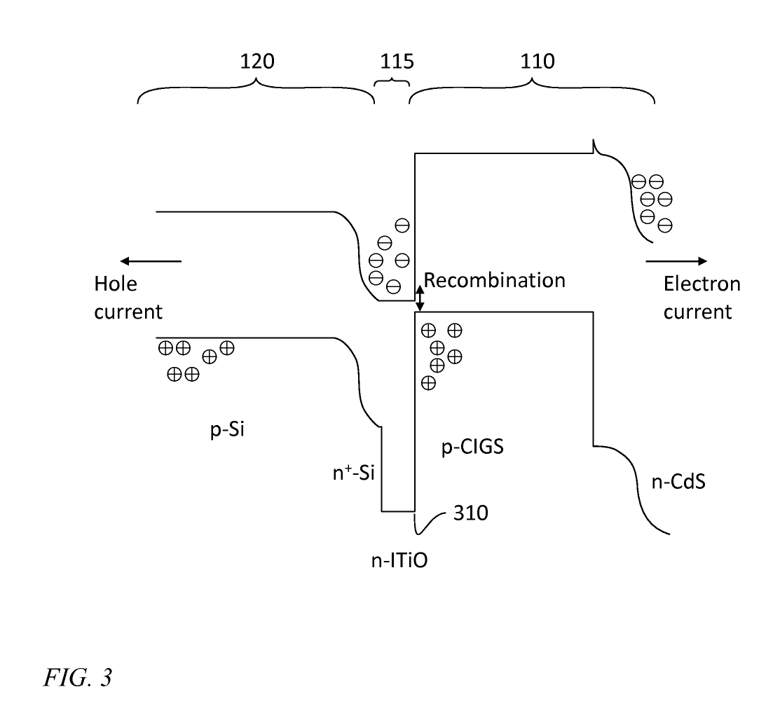

Referring to the energy band diagram of FIG. 3, in one embodiment the bottom TCO layer that forms the joining layer 115 facilitates the flow of current through a CIGS/TCO/silicon tandem solar cell according to the band diagram illustrated. In the bottom cell 120 and in the joining layer 115, electrons flow from left to right (and holes flow from right to left), the right side of FIG. 3 corresponding to the top of the tandem solar cell. Electrons accumulate in a well in the conduction band, in the joining layer 115. In the top cell 110, electrons flow also from left to right (and holes flow from right to left). Holes accumulate in the CIGS layer near the interface with the joining layer 115. The conduction band in the bottom TCO layer may be only slightly higher than the valence band in the CIGS layer, and the interface between the joining layer 115 and the CIGS layer may form a recombination contact, at which electrons in the bottom TCO layer recombine with holes in the CIGS layer, with relatively little power loss.

In addition to facilitating the flow of current, the joining layer 115 may passivate the upper surface of the silicon bottom cell 120. Absent a passivation layer, the efficiency of a silicon solar cell may be significantly degraded by surface recombination that may result from dangling bonds at the top and bottom surfaces of the solar cell. Passivation mechanisms include chemical passivation, in which a passivation layer closes dangling bonds at the surface, and field-effect passivation, in which a passivation layer produces a local field that repels either electrons or holes, so that one type of carrier is substantially absent, at the surface. A bottom TCO layer may provide passivation at the upper surface of the silicon bottom cell 120. In other embodiments as described in further detail below, an additional passivation layer may be used.

The bottom TCO layer may be sufficiently thin that it does not significantly attenuate the light transmitted through it, and that the resistive voltage drop across the layer is small, while being sufficiently thick that it may be readily fabricated. For example, if a TCO layer less than 50 nanometers thick is formed, the bottom TCO layer may have a tendency to peel off of the bottom cell 120, or one or more of the constituent elements of the bottom TCO layer may diffuse out of the bottom TCO layer and into the CIGS layer during fabrication of the CIGS layer, altering the properties of the TCO layer. In some embodiments, the bottom TCO layer is between 50 nm and 1000 nm thick.

The doping of the bottom TCO layer may be selected to be sufficiently high to provide adequate conductivity through the layer, while not being sufficiently high that free carrier absorption results in unacceptable optical loss. In some embodiments the doping level is selected to provide electron densities in the range 1.0×10¹⁹-1.0×10²⁰ cm⁻³.

In other embodiments, the TCO of the bottom TCO layer may be zinc oxide, doped zinc oxide, e.g., indium titanium oxide (ITiO) which may consist of titanium-doped indium oxide, boron-doped zinc oxide (BZO) or gallium-doped zinc oxide, vanadium oxide, molybdenum oxide, indium-doped molybdenum oxide, indium-doped tin oxide (ITO), titanium dioxide, or fluorine-doped tin oxide (FTO). If AZO is used, it may be doped with 0.5% to 4% aluminum. As used herein, a “transparent conducting oxide” or “TCO” is a material that is a doped or undoped metal oxide, with a conductivity of at least 0.005 ohm-cm and an optical transmissivity, through a one micron thick layer, of at least 50% over the wavelength range from 700 nm to 1100 nm. A TCO with a bandgap greater than the bandgap of the top cell 110 may be used for the bottom TCO layer to avoid excess optical loss in the joining layer 115. Similarly the TCO material used for the top TCO layer 220 may have a bandgap much greater than the bandgap of the top cell 110 to avoid excess optical loss.

In addition to being sufficiently conductive to conduct current between the top cell 110 and the bottom cell 120 without a significant voltage drop, and being sufficiently transparent to transmit light to the bottom cell 120, the bottom TCO layer may have other characteristics making it suitable for use in embodiments of the present invention. For example, the extent to which certain TCOs passivate the top surface of the bottom cell 120, and their compatibility with fabrication processes for other elements of the tandem solar cell may be factors in the selection of a TCO for the bottom TCO layer.

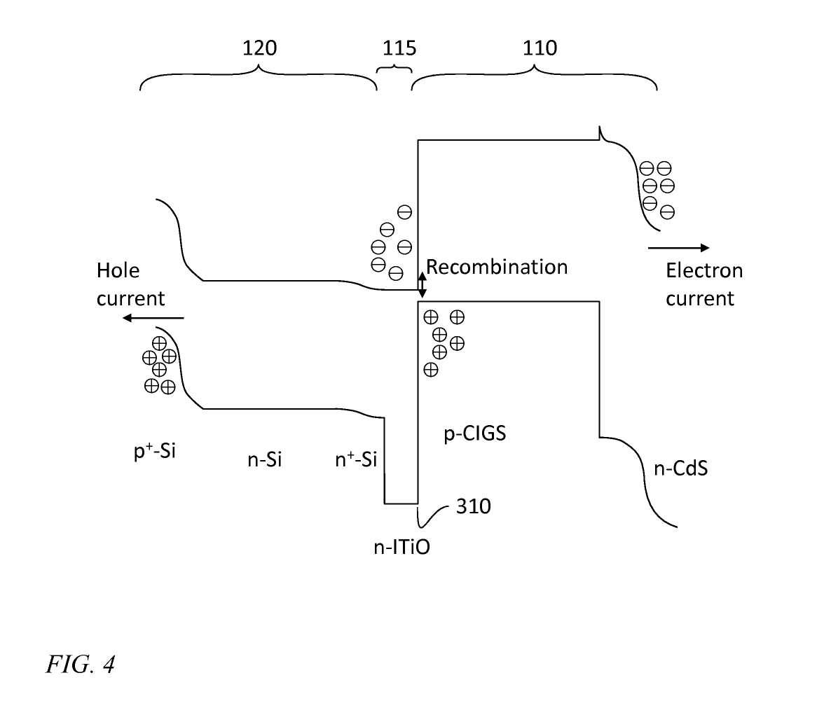

In some embodiments, the bottom cell 120 may be an n-type silicon solar cell, i.e., a solar cell in which the substrate (which forms the base) is n-type silicon, and the emitter is a thin layer of p⁺ silicon on the bottom (or “back”) of the substrate. The top surface of the n-type solar cell may include a thin n⁺ layer. Referring to FIG. 4, in one embodiment the band diagram for a tandem solar cell including an n-type bottom cell 120 may differ from the band diagram (FIG. 3) of a tandem cell including a p-type bottom cell 120 in that there may be small band shift from the n+ layer to the n-type substrate, and a junction at the back of the cell, between the base and the emitter.

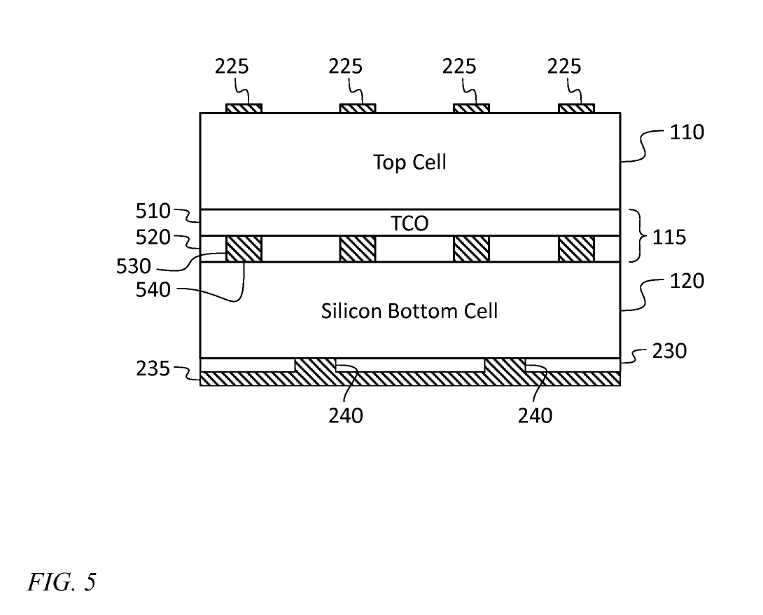

Referring to FIG. 5, in some embodiments the joining layer 115 may be a composite layer including a bottom TCO layer 510, and a dielectric passivation layer 520. As used herein, a “layer” is a structure having two substantially parallel surfaces. A “simple layer” is composed of a single, substantially uniform material, and a “composite layer” includes more than one material. A composite layer may be composed, for example, of two or more simple layers.

The dielectric passivation layer 520 may have a grid of holes 530 filled through which metal contacts 540 may connect the bottom TCO layer 510 and the bottom cell 120. In this embodiment, the dielectric passivation layer 520 may provide additional or potentially superior passivation to that provided by the bottom TCO layer 510. In embodiments in which the top cell material has low conductivity (e.g., CIGS), the current from the top cell 110 may flow vertically into the TCO layer, laterally to the nearest hole 530, and through the metal contact 540 in the hole 530 to the bottom cell 120. Because in this embodiment the bottom TCO layer may conduct current laterally (i.e., in-plane) over distances that may be large (compared to the embodiment of FIG. 2, in which the conduction distance is the bottom TCO layer thickness), the bottom TCO layer may be made (at the expense of some increase in optical loss) to be thicker and more conductive (e.g., more highly doped) than in embodiments in which the current flows only vertically through the bottom TCO layer. The dielectric passivation layer 520 may be composed of silicon dioxide or silicon nitride, or it may be a composite layer including a silicon nitride layer on a silicon dioxide layer. The dielectric passivation layer 520 may have a total thickness of between 50 nm and 100 nm. The holes 530 and metal contacts 540 may have diameters of about 5 microns to 100 microns and a spacing that does not create unacceptable obscuration (e.g., the obscuration may be about 3%), while providing an acceptable density of current paths through the dielectric passivation layer 520. The holes 530 may be on hexagonal grid. Certain metals (e.g., aluminum and silver), if used as a contact material in the holes 530, may interfere with the fabrication of the top cell 110 (e.g., the CIGS top cell). To avoid such difficulties other metals such as nickel or molybdenum may be used.

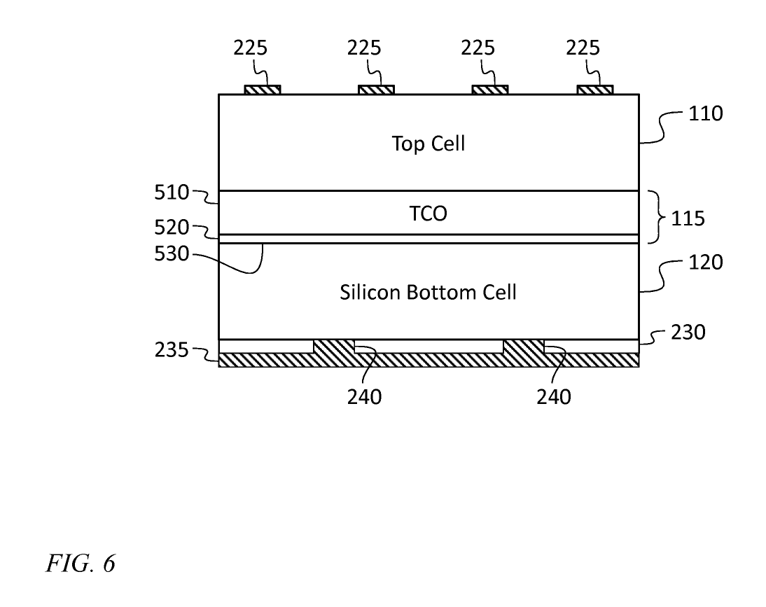

Referring to FIG. 6, in another embodiment the dielectric passivation layer 520 may be made sufficiently thin (e.g., between 1.5 and 3 nm thick) to allow electrons to tunnel through it, eliminating the need for metal contacts providing conductive paths through holes in the dielectric passivation layer 520, and also eliminating the need for the bottom TCO layer to carry in-plane currents. Again referring to FIG. 6, in another embodiment, the dielectric passivation layer may be made sufficiently thin to enable electron tunneling, and be overlayed with a thin (e.g. 5-40 nm) doped amorphous Si layer between layers 520 and 510 to produce improved passivation of the bottom cell 120.

In some embodiments the top cell 110 is a different composition from CIGS/CdS. The top cell composition and structure may be selected so that the top cell 110 has a bandgap of about 1.7 eV, high photoelectric efficiency for wavelengths shorter than the cutoff wavelength, and low optical loss (i.e., high transmittance) for wavelengths longer than the cutoff wavelength. If the tandem solar cell is to be fabricated by first forming a silicon bottom cell 120, and then forming the joining layer 115 and the top cell 110 on the silicon bottom cell 120, then a top cell 110 that may be fabricated with a relatively low temperature process (e.g., a process that does not require temperatures above 700° C.) may be used to avoid damaging the silicon bottom cell 120. If a joining layer 115 is used that may be damaged at lower temperatures than 700° C., then a top cell that may be fabricated at a correspondingly lower temperature may be used.

In some embodiments, a cadmium telluride (or a ternary compound such as CdMgTe) top cell is used. If such a top cell is used in an embodiment with a thick dielectric passivation layer 520 having holes 530 with metal contacts 540, then the use of iron or iron-containing alloys may be avoided in the metal contacts 540, to avoid interference with the fabrication of the top cell 110. Aluminum may be avoided also. The cadmium telluride top cell may be alloyed with zinc or magnesium to adjust the bandgap (which may be 1.5 eV for cadmium telluride) to 1.7 eV, so that the photocurrents (or “photoelectric currents”) in the top cell 110 and in the bottom cell 120 may be more nearly equal.

In other embodiments a perovskite top cell is used. For example, the perovskite may be methyl ammonium lead iodide, i.e., CH₃NH₃PbI₃. The composition may be adjusted, e.g., by substituting chlorine or bromine for a fraction of the iodine, to adjust the bandgap, e.g., from 1.5 eV to 1.7 eV. In other embodiments the top cell may be an amorphous silicon solar cell, or a cadmium zinc telluride solar cell.

The thickness of the top cell 110 may be adjusted according to several criteria. As the thickness is increased, the efficiency of the top cell 110 may increase as a result of increased photon absorption. An increase in the top cell thickness, however, may also result in a reduction of the transmissivity of the top cell 110 for long wavelength photons, resulting in a decrease in bottom cell photocurrent. As such, the top cell thickness may be selected to be just sufficient to absorb most of the light with wavelengths below the cutoff wavelength. In embodiments in which the bandgap of the top cell 110 is less than 1.7 eV, the top cell 110 may capture a correspondingly greater portion of the solar spectrum and, if the top cell 110 is sufficiently thick to capture most of the light with wavelengths below the cutoff wavelength, the top cell 110 may generate significantly more photocurrent than the bottom cell 120 (which, in such embodiments, receives a reduced portion of the solar spectrum). This may result in a loss of efficiency. This effect may be partially mitigated by reducing the thickness of the top cell 110 so that it absorbs a smaller fraction of the light with wavelengths below the cutoff wavelength, restoring current balance (or reducing the current imbalance) between the top and bottom cells.

Combinations of conventional fabrication processes may be employed to fabricate tandem solar cells according to embodiments of the present invention. For example, a silicon solar cell fabricated according to methods known in the art may be passivated with a silicon dioxide layer using a thermal oxidation process. A silicon nitride passivation layer may then be formed on the silicon dioxide layer using plasma enhanced chemical vapor deposition (PECVD). If the passivation layer on the bottom surface of the silicon solar cell is the same as the passivation layer on the top surface, the two passivation layers may be formed simultaneously, in one processing step.

Other layers or structures may then be formed on the top of the silicon solar cell, such as holes 530, containing metal contacts 540, in the passivation layer as described above. In some embodiments, the top surface of the silicon solar cell is textured before another layer (e.g., a TCO layer) is formed on the silicon solar cell, to reduce the reflection due to a mismatch in refractive index (e.g., a mismatch in refractive index between silicon and the TCO) at the top surface of the silicon solar cell.

The bottom TCO layer may be formed, for example, by sputtering, e.g., RF or DC sputtering. In other embodiments the bottom TCO layer is formed using e-beam evaporation or thermal evaporation from a target.

A CIGS layer (for the top cell 110) may be formed by sputtering followed by annealing. For example, copper indium and gallium may be sputtered in the desired ratios from a sputtering target, and a high temperature annealing step may then be performed in hydrogen sulfide gas (H₂S), the latter step being a sulfurization process to form CIGS. A cadmium sulfide emitter may be formed on the cadmium telluride base using a chemical bath deposition (CBD) process. For example, a low temperature bath of thiourea may be used to deposit sulfur, and a cadmium salt bath may be used to deposit cadmium, to form a thin cadmium sulfide emitter layer.

To fabricate a cadmium telluride top cell 110, vapor transport deposition or closed space sublimation may be used to form the cadmium telluride base, and a cadmium sulfide emitter may be formed on the cadmium telluride base using a chemical bath deposition (CBD) process. A perovskite top cell may be fabricated using solution based processing. After depositing an appropriate electron or hole collection layer, solutions of the perovskite may be spun onto the silicon bottom cell to a given thickness (after the formation of the joining layer 115), and the cell may then be heated to remove the solvent. In other embodiments, evaporation may be used to form a perovskite top cell.

After the top cell 110 has been formed, metal layers may be formed on the top (or front) surface and on the bottom (or back) surface of the tandem solar cell. The back contact may be a blanket metal layer deposited by evaporation or plating, after holes are formed in the bottom passivation layer. These holes may allow the metal to extend through the passivation layer to contact the silicon.

Gridlines may be formed on the front surface using a low-temperature process. If a cadmium sulfide emitter is used, forming a junction that cannot withstand high temperatures, the use of a low-temperature process to form gridlines may avoid damage to the junction. The gridlines may be formed by evaporating silver onto the front surface using a mechanical shadow mask or a photolithographic liftoff process, or by evaporating a thin initial conductive layer in the pattern of the gridlines, and electroplating thicker grid lines onto the initial layer. In some embodiments the process used to form the front gridlines does not raise the top cell temperature above 150° C.

It will be understood that spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it may be the only layer between the two layers, or one or more intervening layers may also be present.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Although exemplary embodiments of a tandem photovoltaic device have been specifically described and illustrated herein, many modifications and variations will be apparent to those skilled in the art. Accordingly, it is to be understood that a tandem photovoltaic device constructed according to principles of this invention may be embodied other than as specifically described herein. The invention is also defined in the following claims, and equivalents thereof.

What is claimed is:

1. A tandem solar cell, comprising:
a first cell configured to generate a photoelectric current when illuminated with light;
a joining layer directly on the first cell; and
a second cell configured to generate a photoelectric current when illuminated with light, the second cell being directly on the joining layer,
wherein the first cell is a silicon solar cell and the joining layer comprises a first transparent conductive oxide layer.

2. The solar cell of claim 1, wherein the joining layer is a simple layer of a transparent conductive oxide.

3. The solar cell of claim 2, wherein the joining layer is less than 1 micron thick.

4. The solar cell of claim 1, wherein the joining layer further comprises a layer of silicon dioxide, the layer of silicon dioxide being directly on the first cell.

5. The solar cell of claim 4, wherein the layer of silicon dioxide has a plurality of holes.

6. The solar cell of claim 5, wherein:
the first transparent conductive oxide layer is directly on the layer of silicon dioxide; and
at least one of the plurality of holes is a through hole extending from a first surface of the layer of silicon dioxide to a second surface of the layer of silicon dioxide, the first surface of the layer of silicon dioxide being directly on the first cell, and the first transparent conductive oxide layer being directly on the second surface of the layer of silicon dioxide.

7. The solar cell of claim 5, wherein at least one of the plurality of holes contains a metal contact forming a conductive path between the first transparent conductive oxide layer and the first cell.

8. The solar cell of claim 4, wherein the layer of silicon dioxide is less than 5 nm thick.

9. The solar cell of claim 1, wherein the transparent conductive oxide is aluminum-doped zinc oxide.

10. The solar cell of claim 1, wherein the transparent conductive oxide is indium-doped tin oxide.

11. The solar cell of claim 1, wherein the transparent conductive oxide is a material selected from the group consisting of titanium-doped indium oxide, zinc oxide, boron-doped zinc oxide, gallium-doped zinc oxide, vanadium oxide, molybdenum oxide, indium-doped molybdenum oxide, titanium dioxide, fluorine-doped tin oxide, and combinations thereof.

12. The solar cell of claim 1, wherein the second cell comprises a layer of copper indium gallium sulfide.

13. The solar cell of claim 12, wherein the copper indium gallium sulfide has a bandgap of about 1.7 eV.

14. The solar cell of claim 12, wherein the second cell further comprises a layer of cadmium sulfide directly on the layer of copper indium gallium sulfide.

15. The solar cell of claim 14, wherein the second cell further comprises a second transparent conductive oxide layer directly on the layer of cadmium sulfide.

16. The solar cell of claim 1, wherein the second cell comprises a layer of copper gallium diselenide.

17. The solar cell of claim 1, wherein the second cell comprises a material selected from the group consisting of perovskites, amorphous silicon, cadmium telluride, cadmium zinc telluride, cadmium magnesium telluride, and combinations thereof.

18. The solar cell of claim 1, wherein the first cell has a textured top surface.

19. A method of fabricating a tandem solar cell, the method comprising:
forming a joining layer directly on a silicon solar cell configured to generate a photoelectric current when illuminated with light, the joining layer comprising a transparent conductive oxide layer; and
forming a second solar cell directly on the joining layer, the second solar cell being configured to generate a photoelectric current when illuminated with light.

20. The method of claim 19, wherein the forming of the joining layer consists of forming the transparent conductive oxide layer directly on the silicon solar cell.

21. The method of claim 19, wherein the forming of the joining layer comprises:
forming a layer of silicon dioxide directly on the silicon solar cell; and
forming the transparent conductive oxide layer directly on the layer of silicon dioxide.

22. The method of claim 21, wherein the layer of silicon dioxide is less than 5 nm thick.

23. The method of claim 21, wherein the forming of the joining layer further comprises:
forming a plurality of through holes in the layer of silicon dioxide; and
forming a metal contact in each of the plurality of through holes.
